(19) United States
(12) Patent Application Publication
(10) Pub. No.: US 2011/0018127 A1
(43) Pub. Date: Jan. 27, 2011

(54) Multilayer UV-Curable Adhesive Film

(76) Inventor: Byoungchul Lee, Cypress, CA (US)

Correspondence Address: Henkel Corporation, 10 Finderne Avenue, Suite B, Bridgewater, NJ, 08807, US

(21) Appl. No.: 12/894,816

(22) Filed: Sep. 30, 2010

Related U.S. Application Data
(63) Continuation of application No. PCT/US2008/058867, filed on Mar. 31, 2008.

(51) Int. Cl. H01L 23/14; H01L 23/12; H01L 21/58; B32B 27/30; B32B 27/38; C09J 7/00

(52) U.S. Cl. 257/729; 257/678; 438/113; 428/343; 428/355 AC; 428/355 EP; 257/E21.505; 257/E23.003; 257/E23.005

(57) ABSTRACT

This invention is an adhesive film comprising (a) a top layer that is substantially UV curable and that has a glass transition temperature of 50° C. or less; and (b) a bottom layer that is substantially not UV-curable. Additional embodiments include a bundled wafer lamination film, a semiconductor wafer with a multilayer adhesive film attached, a process for attaching a semiconductor die to a substrate, and a method of preventing individually diced dies from sticking to one another.

### CROSS-REFERENCE TO RELATED APPLICATIONS

This application is a continuation of International Application No. PCT/US2008/058867 filed Mar. 31, 2008, the contents of which are incorporated herein by reference.

### BACKGROUND OF THE INVENTION

This invention relates to multilayer adhesive films for use in semiconductor packages, processes for using those films, and semiconductor packages assembled with those films. The films of this invention, when used in bundled wafer backside lamination processes, do not cause individual dies to stick together after dicing.

Adhesive films are often used in the fabrication of semiconductor packages, for example, in attaching silicon semiconductor dies to substrates. Generally, these films are compositions that are applied to a carrier and then B-staged to partially cure or dry the composition into a film form. The film may then be applied to a dicing tape, the carrier removed, and the exposed side of the film applied to the back side of a semiconductor wafer, thereby sandwiching the adhesive film between the back side of the wafer and the dicing tape. This enables the wafer to be diced into individual dies having adhesive film attached, the combination of die and film, including multilayer film, hereinafter called a die structure. The die structures are then picked off the dicing tape and placed on a substrate with the adhesive film adjacent to the substrate. The adhesive film, when cured, typically with the application of heat, bonds the die to the substrate. Due to operational considerations, it may necessary to have a time delay between dicing the wafer into individual dies and picking up the die for bonding to a substrate. In these cases it has been observed that the adhesive film on the back of individual dies sometimes sticks to the adhesive film on the back of adjacent dies, causing more than one die to be removed from the carrier or dicing tape. This is problematic and it would be preferable to have an adhesive film that will not cause dies to stick together after dicing and before die attach.

### SUMMARY OF THE INVENTION

This invention is an adhesive film comprising (a) a top layer that is substantially UV curable and that has a glass transition temperature of 50° C. or less; and (b) a bottom layer that is substantially not UV-curable.

In another embodiment, this invention is an adhesive film laminated on a support tape wherein the adhesive film comprises (a) a top layer that is substantially UV curable and that has a glass transition temperature of 50° C. or less; and (b) a bottom layer that is substantially not UV-curable

In a further embodiment, this invention is a semiconductor wafer attached to an adhesive film, in which the adhesive film comprises (a) a top layer that is adhered to the semiconductor wafer, is substantially UV curable, and has a glass transition temperature of 50° C. or less; and (b) a bottom layer that is substantially not UV-curable.

In another embodiment, this invention is a process for attaching a semiconductor die to a substrate comprising the steps of:

1. providing an adhesive film comprising (a) a top layer that is substantially UV curable and has a glass transition temperature of 50° C. or less; and (b) a bottom layer that is substantially not UV-curable;

2. providing a support tape having a backing side and an adhesive side;

3. attaching the adhesive film to the support tape by contacting the bottom layer of the adhesive film with the adhesive side of the support tape, thereby exposing the top layer of the adhesive film, and thereby forming a bundled wafer backside lamination film;

4. providing a semiconductor wafer having an active side and an inactive side;

5. attaching the bundled wafer backside lamination film to the semiconductor wafer by contacting the top layer of the adhesive film with the inactive side of the semiconductor wafer;

6. advancing the top layer;

7. dicing the semiconductor wafer and attached multilayer adhesive film into a plurality of individual die structures;

8. picking up a chosen individual die structure;

9. providing a substrate;

10. placing the chosen individual die structure on the substrate such that the adhesive film is disposed between the back side of the die and the substrate; and

11. attaching the individual die structure to the substrate using heat.

In another embodiment, this invention is a method of preventing individually diced dies from sticking to one another. The method comprises the steps of:

1. providing an adhesive film comprising (a) a top layer that is substantially UV curable and has a glass transition temperature of 50° C. or less; and (b) a bottom layer that is substantially not UV-curable;

2. providing a support tape having a backing side and an adhesive side;

3. attaching the adhesive film to the support tape by contacting the bottom layer of the adhesive film with the adhesive side of the support tape, thereby exposing the top layer of the adhesive film, and thereby forming a bundled wafer backside lamination film;

4. providing a semiconductor wafer having an active side and an inactive side;

5. attaching the bundled wafer backside lamination film to the semiconductor wafer by contacting the top layer of the adhesive film with the inactive side of the semiconductor wafer;

6. advancing the top layer;

7. dicing the semiconductor wafer and attached multilayer adhesive film into a plurality of individual die structures; and

8. picking up a chosen individual die structure.

### BRIEF DESCRIPTION OF THE DRAWINGS

The present invention can be more fully understood by reading the following detailed description, with reference made to the accompanying drawings, wherein:

FIG. 1 is a cross-sectional view of the multilayer film of this invention;

FIG. 2 is a cross-sectional view of a semiconductor wafer with the multilayer adhesive film of this invention attached thereto;

FIG. 3 is a cross-sectional view of the bundled wafer lamination film of this invention;

FIG. 4 is a cross-sectional view of a semiconductor wafer with the bundled wafer lamination film of this invention attached thereto;

FIG. 5 is a cross-sectional view of a wafer diced into individual die structures according to this invention;

FIG. 6 is a cross-sectional view of a semiconductor die attached to a substrate according to this invention; and

FIG. 7 PRIOR ART depicts a cross-sectional view of the re-attach problem experienced with prior art adhesive films.

### DEFINITIONS

The term “alkyl” refers to a branched or un-branched saturated hydrocarbon group of 1 to 24 carbon atoms, such as methyl (“Me”), ethyl (“Et”), n-propyl, isopropyl, n-butyl, isobutyl, t-butyl, octyl, decyl, and the like.

The term “advancing” means curing or partially curing.

The term “effective amount” of a compound, product, or composition means a sufficient amount of the compound, product or composition to provide the desired results. The exact amount required will vary from package to package, depending on the particular compound, product or composition used, its mode of administration, and the like. Thus, it is not always possible to specify an exact amount; however, an effective amount may be determined by one of ordinary skill in the art using only routine experimentation.

The term “suitable” refers to a moiety that is compatible with the compounds, products, or compositions as provided herein for the stated purpose. Suitability for the stated purpose may be determined by one of ordinary skill in the art using only routine experimentation.

The term “substituted” is used to refer, generally, to a carbon or suitable heteroatom having a hydrogen atom or other atom removed and replaced with a further moiety. Moreover, it is intended that “substituted” refer to substitutions that do not change the basic and novel utility of the underlying compounds, products or compositions of the present invention.

The term “B-staging” (and its variants) is used to refer to the processing of a material by heat or irradiation so that if the material is dissolved or dispersed in a solvent, the solvent is evaporated off with or without partial curing of the material, or if the material is neat with no solvent, the material is partially cured to a tacky or more hardened state. If the material is a flow-able adhesive, B-staging will provide extremely low flow without fully curing, such that additional curing may be performed after the adhesive is used to join one article to another. The reduction in flow may be accomplished by evaporation of a solvent, partial advancement or curing of a resin or polymer, or both.

The term “curing agent” is used to refer to any material or combination of materials that initiate, propagate, or accelerate cure of the composition and includes but is not limited to accelerators, catalysts, initiators, and hardeners.

The term “UV-curable” is used to refer to any resin that is polymerized and/or crosslinked by the application of ultraviolet radiation.

The term “Tg” or “glass transition temperature” is used to refer to the temperature at which a material transitions from a glassy state to a rubbery state.

### DETAILED DESCRIPTION OF THE INVENTION

The invention will now be described in further detail by reference to the drawings, which illustrate various embodiments of the invention. The drawings are diagrammatic, showing features of the invention and their relation to other features and structures, and are not made to scale. For improved clarity of presentation, in the Figures (FIGS) illustrating embodiments of the invention, elements corresponding to elements shown in other drawings are not all particularly re-labeled, although they are all readily identifiable in all the Figures.

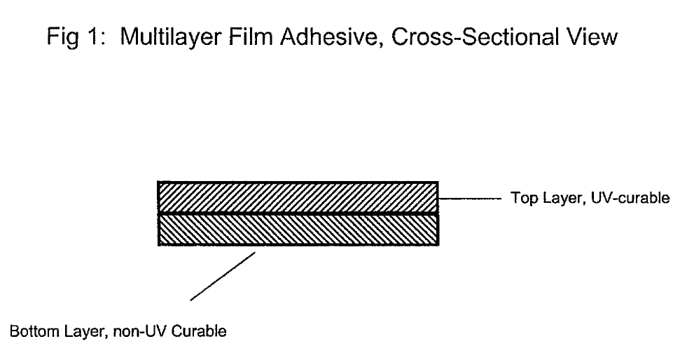

In one embodiment, this invention is a multilayer adhesive film. The film has at least a top layer and a bottom layer. FIG. 1 is a cross-sectional view of one embodiment of the film of this invention, having only a top layer and a bottom layer. Optionally, there may be additional layers (not shown) between the top and the bottom, if needed to impart additional desirable performance attributes to the adhesive film. The top layer has a glass transition temperature of 50° C. or less and is substantially UV curable. The bottom layer is substantially not UV-curable.

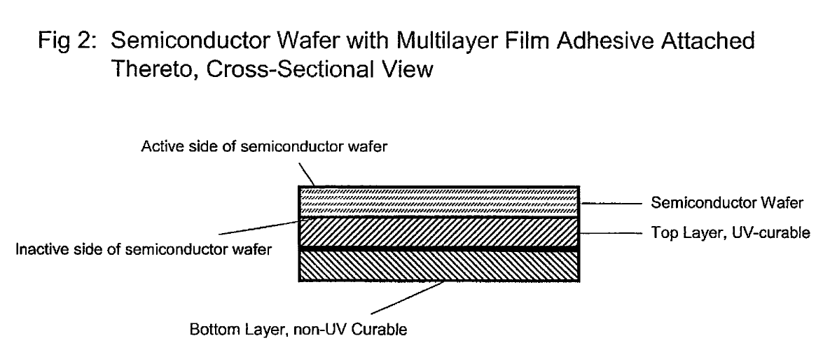

FIG. 2 shows a cross-sectional view of one embodiment of this invention, in which the multilayer adhesive film, described above, has been attached to the back side of a semiconductor wafer. The semiconductor wafer has an active side and a back side opposed to the active side. In the embodiment illustrated in FIG. 2, the multilayer adhesive film is applied to the semiconductor wafer such that the top layer of the film is in direct contact with the back side of the semiconductor wafer. In another embodiment (not shown), the multilayer adhesive film is applied to the front, or active, side of the semiconductor wafer.

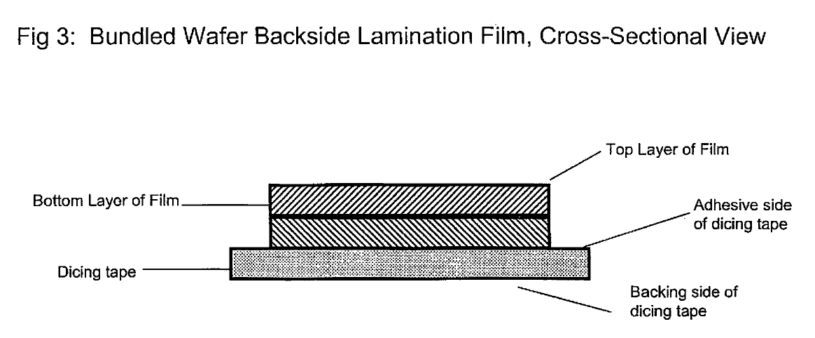

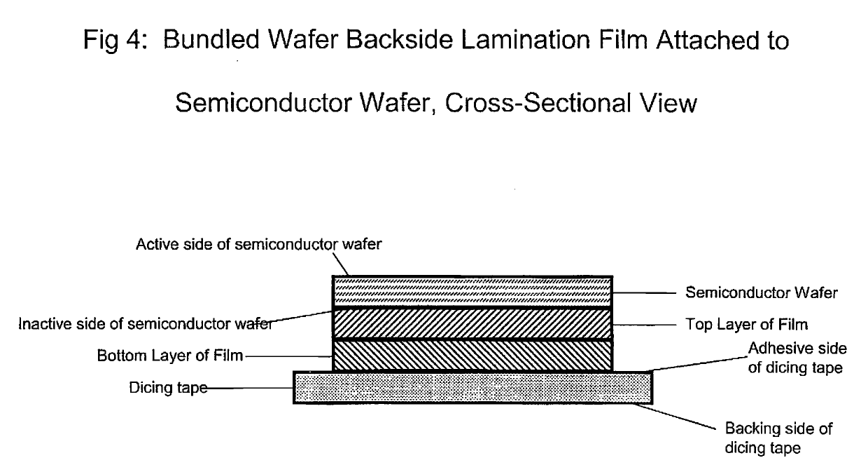

In another embodiment, this invention is the multilayer adhesive film described above laminated on a support tape. One example of this embodiment, a bundled wafer lamination (BWL) film, is illustrated in FIG. 3. In this embodiment, the support tape is a dicing tape and the multilayer adhesive film described above is attached to the dicing tape such that the bottom layer of the film is in direct contact with the adhesive side of the dicing tape. The BWL film may then be attached to a semiconductor wafer to form another embodiment of this invention, as illustrated in FIG. 4. In this embodiment, the multilayer adhesive film is sandwiched between the semiconductor wafer and the dicing tape such that the top layer of the film is in contact with the inactive side, or back side, of the semiconductor wafer and the bottom layer of the film is in contact with the dicing tape. In this embodiment, the BWL film may be referred to as a bundled wafer backside lamination (BWBL) film. In another embodiment (not shown), the multilayer adhesive film is sandwiched between the semiconductor wafer and the dicing tape such that the top layer of the film is in contact with the active side of the semiconductor wafer and the bottom layer of the film is in contact with the dicing tape.

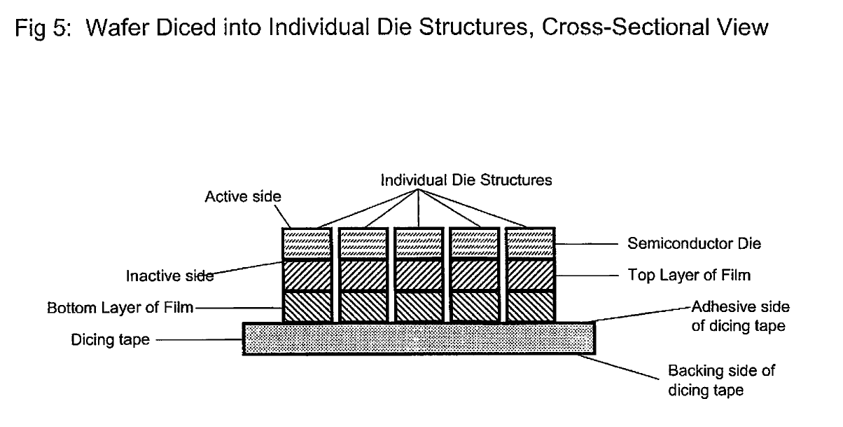

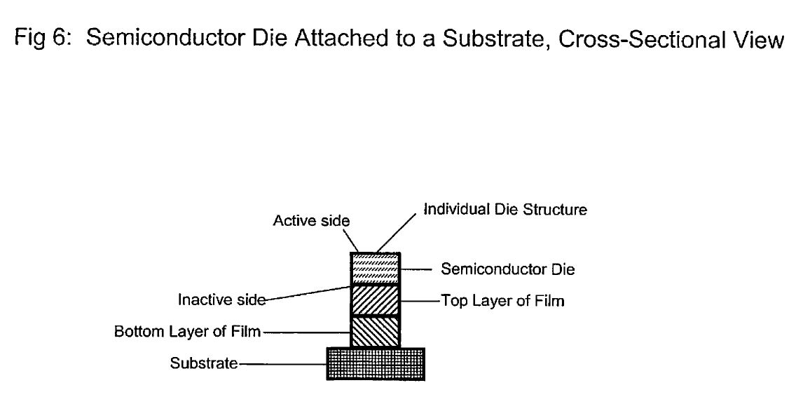

Another embodiment of this invention is a process for attaching a semiconductor die to a substrate. First, a BWBL film is formed attaching the multilayer adhesive film to a dicing tape as described above. Next, the BWBL film is attached to a semiconductor wafer such that the top layer of the film is in direct contact with the back side of the wafer. Then, the top layer of the multilayer adhesive film is advanced through the application of ultraviolet radiation. The advancing of the top layer may involve either partial or complete curing, so long as the amount of curing is adequate to prevent sticking of the dies during die pickup. Next, the semiconductor wafer, along with the multilayer adhesive film attached thereto, is diced, forming a plurality of individual die structures, as illustrated in FIG. 5. A chosen individual die structure is then picked up and placed on a substrate such that the adhesive film is disposed between the die and the substrate. Finally, the die is attached to the substrate by applying heat to cure the bottom layer of the multilayer adhesive film. FIG. 6 shows a cross-sectional view of a die attached to a substrate using this process.

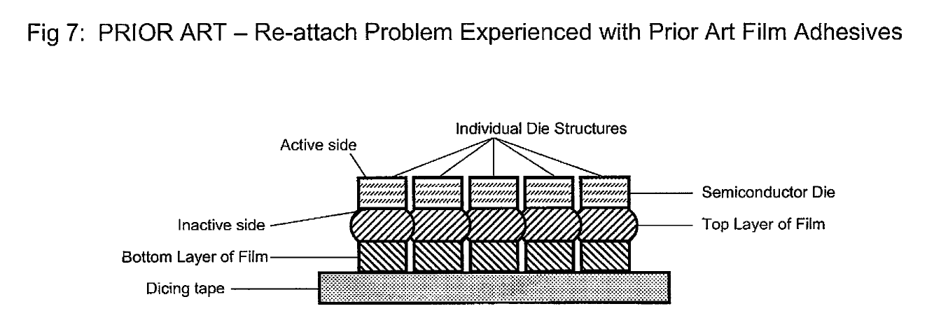

The top layer of the multilayer adhesive film has a glass transition temperature (Tg) of 50° C. or less and is substantially UV-curable. In one embodiment the top layer comprises (i) a UV-curable resin and (ii) a photoinitiator. The Tg is measured after the film has been formed (i.e. after the composition has been b-staged or dried to form a film), but before any UV curing of the film. The low Tg enables the film to flow sufficiently for attachment to a semiconductor wafer at a relatively low temperature. In one embodiment the Tg of the top layer is less than 20° C. In another embodiment the Tg of the top layer is between 0 and 20° C. The UV-curable resin and photoinitiator enable the top layer to be advanced after attachment to a semiconductor wafer to prevent sticking of adjacent dies after dicing. Films are typically applied to semiconductor wafers using a thermal process such as lamination. It is generally desirable to have a lamination temperature of less than 80° C., and sometimes less than 65° C. is required. Low lamination temperatures are required for two reasons. First, lamination at high temperatures tends to advance (partially cure) the resin in the adhesive film. This can limit worklife of the film, and can also inhibit flow, which interferes with later bonding of the die to the substrate. Second, lamination at higher temperatures can cause the semiconductor wafer to warp. This is especially problematic as the semiconductor industry migrates to thinner wafers, which are inherently more susceptible to warpage issues. Unfortunately, the low Tg of the top layer which enables it to be laminated at low temperatures also enables the film to flow slightly at room temperature. Thus, after the film is laminated to a wafer and diced into individual die, if the die are not immediately picked and placed on a substrate there is a tendency for the adhesive film on adjacent dies to flow enough to come in contact with one another. Since the resins used in the top layer are frequently sticky in order to facilitate lamination to the wafer, this flow can cause the dies to stick together, or “re-attach”. This problem is illustrated in FIG. 7, which shows a prior art adhesive film that flows after dicing, leading to re-attach. In the present invention, the UV-curable resin and the photoinitiator are required so that after the film has been laminated to a wafer, the top layer of the film may be substantially advanced, or cured. This increases the molecular weight, and thereby the melt viscosity, of the top layer which helps to prevent flow of the adhesive at ambient conditions, such as those experienced during storage. This alleviates the sticking, or re-attach, problem.

The UV curable resin in the top layer of the multilayer adhesive film may be any that may be reacted, advanced, crosslinked, or polymerized in the presence of ultraviolet light. Although any UV curable resin may be used, non-limiting examples of suitable UV curable resins include maleimides, acrylates, vinyl ethers, and styrenes. The UV curable resin will be present in an effective amount, typically between 5 and 100 wt % of the top layer composition, excluding filler content.

In one embodiment, the UV curable resin is a solid aromatic bismaleimide (BMI) resin. Suitable solid BMI resins are those having the generic structure

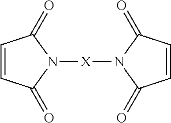

in which X is an aromatic group; exemplary aromatic groups include:

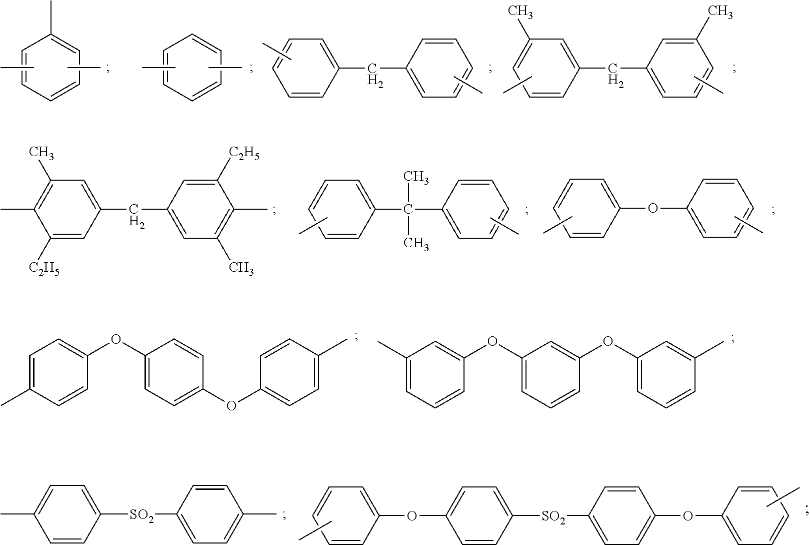

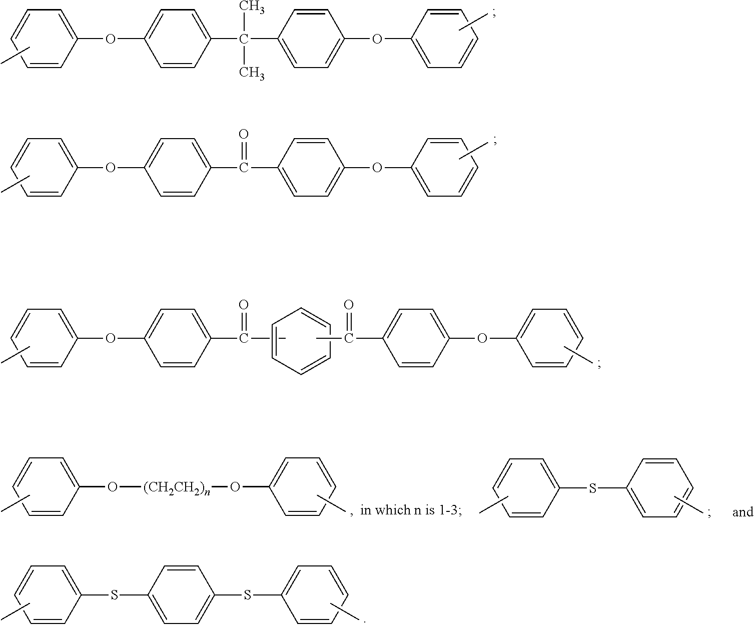

Bismaleimide resins having these X bridging groups are commercially available, and can be obtained, for example, from Sartomer (USA) or HOS-Technic GmbH (Austria).

In another embodiment, the UV-curable resin is a maleimide resin having the generic structure

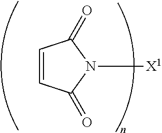

in which n is 1 to 3 and X¹ is an aliphatic or aromatic group. Exemplary X¹ entities include, poly(butadienes), poly(carbonates), poly(urethanes), poly(ethers), poly(esters), simple hydrocarbons, and simple hydrocarbons containing functionalities such as carbonyl, carboxyl, amide, carbamate, urea, or ether. These types of resins are commercially available and can be obtained, for example, from National Starch and Chemical Company and Dainippon Ink and Chemical, Inc.

In one embodiment the UV-curable resin is phenol novolac polyimide:

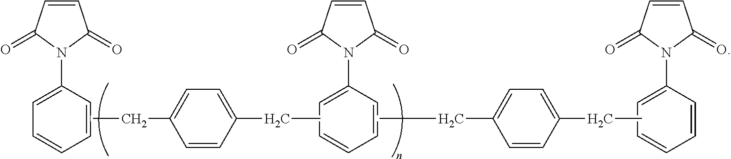

In another embodiment the UV-curable resin is 3-maleimidopropionic acid/dimethyloctanol adduct.

In a further embodiment, the UV-curable resin is a maleimide resin selected from the group consisting of:

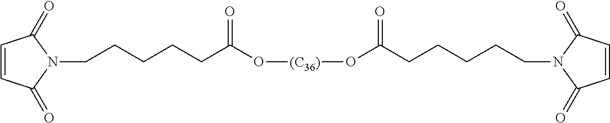

in which C₃₆ represents a linear or branched chain (with or without cyclic moieties) of 36 carbon atoms;

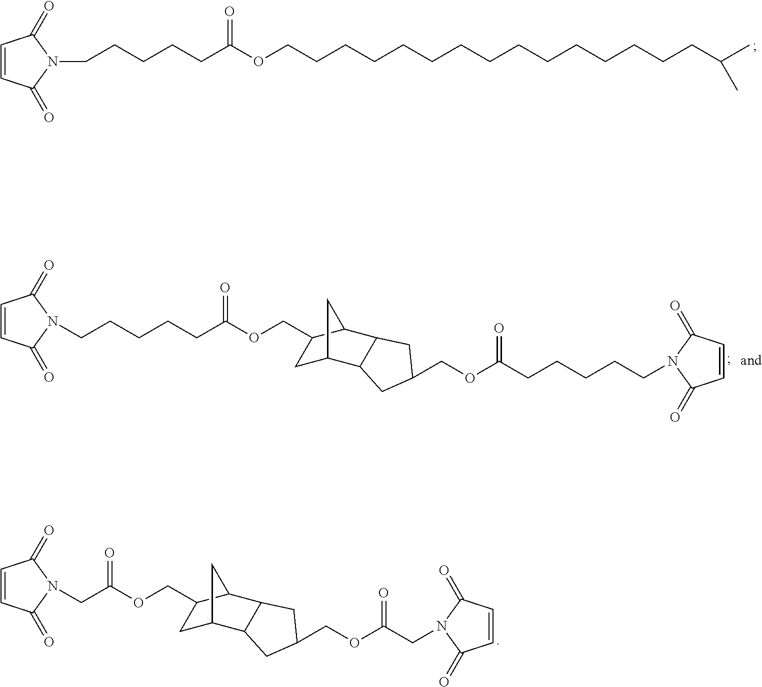

In one embodiment the UV-curable resin is the maleimide 2,5-furandione reaction product with aniline-1,4-bis(chloromethyl)benzene polymer.

Examples of suitable acrylate resins include those having the generic structure

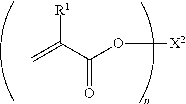

in which n is 1 to 6, R¹ is —H or —CH₃ and X² is an aromatic or aliphatic group. Exemplary X² entities include, but are not limited to, poly(butadienes), poly(carbonates), poly(urethanes), poly(ethers), poly(esters), simple hydrocarbons, and simple hydrocarbons containing functionalities such as carbonyl, carboxyl, amide, carbamate, urea, or ether. Commercially available materials include butyl(meth)acrylate, isobutyl(meth)acrylate, tricyclodecanedimethanol diacrylate, 2-ethyl hexyl(meth)acrylate, isodecyl(meth)acrylate, n-lauryl (meth)acrylate, alkyl(meth)acrylate, tridecyl(meth)acrylate, n-stearyl(meth)acrylate, cyclohexyl(meth)-acrylate, tetrahydrofurfuryl(meth)acrylate, 2-phenoxy ethyl(meth)acrylate, isobornyl(meth)acrylate, 1,4-butanediol di(meth)acrylate, 1.6 hexanediol di(meth)acrylate, 1,9-nonandiol di(meth)acrylate, perfluorooctylethyl-(meth)acrylate, 1,10 decandiol di(meth)acrylate, nonylphenol polypropoxylate (meth)acrylate, and polypentoxylate tetrahydrofurfuryl acrylate, available from Kyoeisha Chemical Co., LTD; polybutadiene urethane dimethacrylate (CN302, NTX6513) and polybutadiene dimethacrylate (CN301, NTX6039, PRO6270) available from Sartomer Company, Inc; polycarbonate urethane diacrylate (ArtResin UN9200A) available from Negami Chemical Industries Co., LTD; acrylated aliphatic urethane oligomers (Ebecryl 230, 264, 265, 270, 284, 4830, 4833, 4834, 4835, 4866, 4881, 4883, 8402, 8800-20R, 8803, 8804) available from Radcure Specialities, Inc; polyester acrylate oligomers (Ebecryl 657, 770, 810, 830, 1657, 1810, 1830) available from Radcure Specialities, Inc.; and epoxy acrylate resins (CN104, 111, 112, 115, 116, 117, 118, 119, 120, 124, 136) available from Sartomer Company, Inc. In one embodiment the acrylate resins are selected from the group consisting of isobornyl acrylate, isobornyl methacrylate, lauryl acrylate, lauryl methacrylate, poly(butadiene) with acrylate functionality and poly(butadiene) with methacrylate functionality.

In one embodiment the UV curable resin is selected from the group consisting of isobornyl acrylate, isobornyl methacrylate, lauryl acrylate, lauryl methacrylate, poly(butadiene) with acrylate functionality and poly(butadiene) with methacrylate functionality.

Examples of suitable vinyl ether resins include those having the generic structure

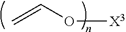

in which n is 1 to 6 and X³ is an aromatic or aliphatic group. Exemplary X³ entities include, but are not limited to, poly(butadienes), poly(carbonates), poly(urethanes), poly(ethers), poly(esters), simple hydrocarbons, and simple hydrocarbons containing functionalities such as carbonyl, carboxyl, amide, carbamate, urea, or ether. Commercially available vinyl ether resins include cyclohenane-dimethanol divinylether; dodecylvinylether; cyclohexyl vinylether; 2-ethylhexyl vinylether; dipropyleneglycol divinylether; hexanediol divinylether; octadecylvinylether; butandiol divinylether available from International Specialty Products (ISP); Vectomer 4010, 4020, 4030, 4040, 4051, 4210, 4220, 4230, 4060, and 5015 available from Sigma-Aldrich, Inc.

Suitable styrene resins include those resins having the generic structure

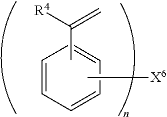

in which n is 1 or greater, R⁴ is —H or —CH₃, and X⁶ is an aliphatic group. Exemplary X⁶ entities include poly(butadienes), poly(carbonates), poly(urethanes), poly(ethers), poly(esters), simple hydrocarbons, and simple hydrocarbons containing functionalities such as carbonyl, carboxyl, amide, carbamate, urea, or ether. These resins are commercially available and can be obtained, for example, from National Starch and Chemical Company or Sigma-Aldrich Co.

The photoinitiator in the top layer of the multilayer adhesive film may be any that initiates, facilitates, or propagates cure of the UV curable resin upon exposure to UV radiation. The photoinitiator will be present in an effective amount, typically 0.1 to 10 wt % of the composition of the top layer before B-staging, excluding solvent content. Suitable photoinitiators include, but are not limited to: 1-hydroxy-cyclohexyl-phenyl ketone, 2-benzyl-2-(dimethylamino)-1-[4-(4-morpholinyl)phenyl]-1-butanone, 2-methyl-1-[4-(methylthio)phenyl]-2-(4-morpholinyl)-1-propanone, (2,2-dimethoxy-1,2-diphenyl-ethane-1-one), 2-hydroxy-2-methoxy-1-phenyl-propan-1-one, 1-hydroxy-cyclohexyl-phenyl-ketone, 2-hydroxy-2-methyl-1-phenyl-1-propanone, bis(2,6-dimethoxybenzoyl)-2,4,4-trimethyl-pentylphosphineoxide, 1-hydroxy-cyclohexyl-phenyl-ketone, and 1-[4-(2-hydroxyethoxy)-phenyl]-2-hydroxy-2-methoxy-1-propane-1-one, and blends of these, available from Ciba Specialty Chemicals; mixture of benzoin normal butyl ethers, ethyl 4-(dimethylamino)benzoate, isopropyl thioxanthone, benzyl dimethyl ketal, oligo (2-hydroxy-2-methyl-1-4 (1-methyl vinyl)phenyl propane, 2-hydroxy-2-methyl-1-phenyl-1-propane, 2-hydroxy-2-methyl-1-phenyl propanone, and blends of these, available from Sartomer Company.

In addition to one or more UV-curable resins, the top layer may contain one or more additional resins that are not substantially UV-curable, i.e., they are not substantially advanced, crosslinked, or polymerized upon exposure to ultraviolet light. Any additional resin in the top layer will be present in an effective amount, typically between 5 and 95 wt % of the top layer composition, excluding filler content. The amount and type of additional resin should be selected to ensure it does not interfere with the ability of the top layer to become non-sticky when advanced with UV radiation.

The top layer of the multilayer adhesive film may be any thickness required for the specific semiconductor package and is typically between 5 and 60 μm. In one embodiment the top layer is between 5 and 30 μm thick. The top layer may be the same thickness as the bottom layer, or it may be a different thickness.

The top layer of the film is substantially cured when exposed to UV radiation after attach to the wafer; in contrast, the bottom layer does not cure substantially when exposed to UV radiation. This enables the resin in the bottom layer to flow and wet-out the rough surface of most substrates, and then cure upon the application of heat during die attach. Thus, the multilayer adhesive film may bond the die to the substrate through a heat cure operation after pick-and-place. The Tg of the bottom layer may be any that gives the desired flow and wet-out desired during die attach. In one embodiment the Tg of the bottom layer is between −30° and 90° C. In another embodiment the Tg of the bottom layer is between 0° and 20° C. If the Tg of the bottom layer is below room temperature, the resins comprising the bottom layer should not be sticky. That way, if the bottom layers of the adhesive film on adjacent dies come into contact with one another they will not adhere, and will not cause sticking or re-attach to occur. It should be noted that in contrast with the resins of the top layer, any resin used in the bottom layer is not typically sticky because it is not required to adhere strongly to the dicing tape.

In one embodiment, the bottom layer of the multilayer adhesive film comprises one or more resins that are not substantially UV-curable, i.e., they are not substantially advanced, crosslinked, or polymerized upon exposure to ultraviolet light.

In another embodiment, the bottom layer of the multilayer adhesive film comprises one or more resins that are UV-curable in the presence of a photoinitiator. In this embodiment photoinitiator is not present in the bottom layer, and consequently the bottom layer is not UV-curable and does not substantially advance or cure upon exposure to UV light. When the bottom layer comprises one or more UV-curable resins (but does not contain UV-initiator), it is preferred that the adhesive film not be used in conjunction with a UV-curable dicing tape since contact with the initiator in the dicing tape could initiate cure in the bottom layer of the adhesive film upon exposure to UV radiation, causing it to adhere too strongly to the dicing tape and potentially leading to die pickup problems.

The bottom layer may comprise just one resin, or a combination of multiple resins. Any resin used may be either solid or liquid at room temperature, and if more than one resin is used they may be any combination of liquids and solids. In one embodiment the bottom layer comprises at least one epoxy resin.

The bottom layer may be any thickness required for the specific semiconductor package and is typically between 20 and 150 μm thick. The bottom layer may be the same thickness as the top layer, or it may be a different thickness.

Examples of resins that are not substantially UV-curable and that are suitable for inclusion in either the top or bottom layer of the adhesive film include epoxies, polyesters, poly(butadienes), polyimides, benzocyclobutene, siliconized olefins, silicone resins, cyanate ester resins, thermoplastic rubbers, polyolefins, siloxanes, or diphenyloxide oligomers.

Suitable epoxy resins include bisphenol, naphthalene, and aliphatic type epoxies. Commercially available materials include bisphenol type epoxy resins (Epiclon 830LVP, 830CRP, 835LV, 850CRP) available from Dainippon Ink & Chemicals, Inc.; naphthalene type epoxy (Epiclon HP4032) available from Dainippon Ink & Chemicals, Inc.; aliphatic epoxy resins (Araldite CY179, 184, 192, 175, 179) available from Ciba Specialty Chemicals, (Epoxy 1234, 249, 206) available from Union Carbide Corporation, and (EHPE-3150) available from Daicel Chemical Industries, Ltd. Other suitable epoxy resins include cycloaliphatic epoxy resins, bisphenol-A type epoxy resins, bisphenol-F type epoxy resins, epoxy novolac resins, biphenyl type epoxy resins, naphthalene type epoxy resins, dicyclopentadiene-phenol type epoxy resins, cresol novolac epoxy resins, reactive epoxy diluents, and mixtures thereof. In one embodiment the epoxy resin is a multi-functional epoxy resin derived from a poly-addition compound of dicyclopentadiene and phenol. In one embodiment the epoxy resin is a rubberized epoxy.

Suitable siliconized olefin resins are obtained by the selective hydrosilation reaction of silicone and divinyl materials, having the generic structure,

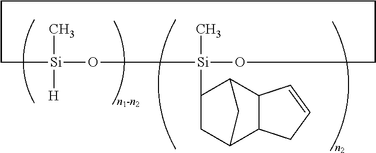

in which n₁ is 2 or more, n₂ is 1 or more and n₁>n₂. These materials are commercially available and can be obtained, for example, from National Starch and Chemical Company.

Suitable silicone resins include reactive silicone resins having the generic structure

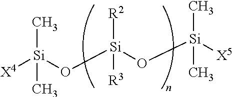

in which n is 0 or any integer, X⁴ and X⁵ are hydrogen, methyl, amine, epoxy, carboxyl, hydroxy, acrylate, methacrylate, mercapto, phenol, or vinyl functional groups, R² and R³ can be —H, —CH₃, vinyl, phenyl, or any hydrocarbon structure with more than two carbons. Commercially available materials include KF8012, KF8002, KF8003, KF-1001, X-22-3710, KF6001, X-22-164C, KF2001, X-22-170DX, X-22-173DX, X-22-174DX X-22-176DX, KF-857, KF862, KF8001, X-22-3367, and X-22-3939A available from Shin-Etsu Silicone International Trading (Shanghai) Co., Ltd.

Suitable cyanate ester resins include those having the generic structure

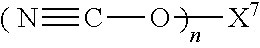

in which n is 1 or larger, and X⁷ is a hydrocarbon group. Exemplary X⁷ entities include bisphenol, phenol or cresol novolac, dicyclopentadiene, polybutadiene, polycarbonate, polyurethane, polyether, or polyester. Commercially available materials include; AroCy L-10, AroCy XU366, AroCy XU371, AroCy XU378, XU71787.02L, and XU 71787.07L, available from Huntsman LLC; Primaset PT30, Primaset PT30 S75, Primaset PT60, Primaset PT60S, Primaset BADCY, Primaset DA230S, Primaset MethylCy, and Primaset LECY, available from Lonza Group Limited; 2-allyphenol cyanate ester, 4-methoxyphenol cyanate ester, 2,2-bis(4-cyanatophenol)-1,1,1,3,3,3-hexafluoropropane, bisphenol A cyanate ester, diallylbisphenol A cyanate ester, 4-phenylphenol cyanate ester, 1,1,1-tris(4-cyanatophenyl)ethane, 4-cumylphenol cyanate ester, 1,1-bis(4-cyanateophenyl)ethane, 2,2,3,4,4,5,5,6,6,7,7-dodecafluorooctanediol dicyanate ester, and 4,4′-bisphenol cyanate ester, available from Oakwood Products, Inc.

Examples of suitable thermoplastic rubbers include carboxy terminated butadiene-nitrile (CTBN) rubber, carboxy terminated butadiene-nitrile (CTBN)/epoxy adduct, acrylate rubber, vinyl-terminated butadiene rubber, and nitrile butadiene rubber (NBR). In one embodiment the CTBN epoxy adduct consists of about 20-80 wt % CTBN and about 20-80 wt % diglycidyl ether bisphenol A: bisphenol A epoxy (DGEBA). A variety of CTBN materials are available from Noveon Inc., and a variety of bisphenol A epoxy materials are available from Dainippon Ink and Chemicals, Inc., and Shell Chemicals. NBR rubbers are commercially available from Zeon Corporation.

Suitable poly(butadiene) polymers include poly(butadienes), epoxidized poly(butadienes), maleic poly(butadienes), acrylated poly(butadienes), butadiene-styrene copolymers, nitrile-butadiene rubber (NBR), and butadiene-acrylonitrile copolymers such as carboxyl terminated butadiene-acrylonitrile (CTBN) rubber. Commercially available materials include homopolymer butadiene (Ricon130, 131, 134, 142, 150, 152, 153, 154, 156, 157, P30D) available from Sartomer Company, Inc; random copolymer of butadiene and styrene (Ricon 100, 181, 184) available from Sartomer Company Inc.; maleinized poly(butadiene) (Ricon 130MA8, 130MA13, 130MA20, 131MA5, 131MA10, 131MA17, 131MA20, 156MA17) available from Sartomer Company, Inc.; acrylated poly(butadienes) (CN302, NTX6513, CN301, NTX6039, PRO6270, Ricacryl 3100, Ricacryl 3500) available from Sartomer Inc.; epoxydized poly(butadienes) (Polybd 600, 605) available from Sartomer Company. Inc. and Epolead PB3600 available from Daicel Chemical Industries, Ltd; and acrylonitrile and butadiene copolymers (Hycar CTBN series, ATBN series, VTBN series and ETBN series) available from Hanse Chemical.

In one embodiment the top layer of the multilayer adhesive film comprises a rubber copolymer, such as a copolymer of butadiene, acrylonitrile, and acrylic acid (CTBN). Suitable rubber copolymers include, for example NIPOL® 1072, available from Zeon Chemicals L.P. The rubber copolymer helps to provide the low Tg required for lamination to the wafer, as well as flexibility.

The bottom layer of the adhesive film comprises a thermal curing agent. The top layer of the adhesive film may optionally include a thermal curing agent, if a thermally curable resin is included in its composition. The thermally curable resin may be the same as the UV-curable resin in the top layer, or it may be a different resin. For instance, bismaleimide resins are capable of initiating by either UV or thermal means. When a bismaleimide resin is utilized in the presence of both a photoinitiator and a thermal initiator, it will primarily cure during UV exposure (after lamination to the semiconductor wafer). However, there may still be some unsaturated bonds in the resin after this cure step. The inclusion of a thermal initiator in addition to the UV initiator enables more complete cure of the resin upon application of heat downstream in the process (typically during die attach cure). The presence of a thermal initiator in the bottom layer enables curing of the bottom layer and attachment to a substrate upon heating.

The thermal curing agent will be present in an effective amount, typically up to 10 wt % of the bottom layer composition before B-staging, excluding solvent content. If utilized in the top layer the thermal curing agent will be present in an effective amount, typically up to 10 wt % of the top layer composition before B-staging, excluding solvent content. Thermal curing agents may be ionic or free radical, depending on the specific resins utilized in each layer. Examples of suitable ionic curing agents include aromatic amines, alycyclic amines, aliphatic amines, tertiary phosphines, triazines, metal salts, aromatic hydroxyl compounds, dicyandiamide, adipic dihydrazide, BF3-amine complexes, amine salts; imidazoles, such as 2-methylimidazole, 2-undecylimidazole, 2-heptadecyl imidazole, 2-phenylimidazole, 2-ethyl 4-methylimidazole, 1-benzyl-2-methylimidazole, 1-propyl-2-methylimidazole, 1-cyanoethyl-2-methylimidazole, 1-cyanoethyl-2-ethyl-4-methylimidazole, 1-cyanoethyl-2-undecylimidazole, 1-cyanoethyl-2-phenylimidazole, 1-guanaminoethyl-2-methylimidazole, addition product of an imidazole and trimellitic acid, and modified imidazole compounds; amines and tertiary amines, such as N,N-dimethyl benzylamine, N,N-dimethylaniline, N,N-dimethyltoluidine, N,N-dimethyl-p-anisidine, p-halogeno-N,N-dimethylaniline, 2-N-ethylanilino ethanol, tri-n-butylamine, pyridine, quinoline, N-methylmorpholine, triethanolamine, triethylenediamine, N,N,N′,N′-tetramethylbutanediamine, N-methylpiperidine, and 4,4′-diamino diphenyl sulfone; phenols, such as phenol, cresol, xylenol, resorcine, and phloroglucin; organic metal salts, such as lead naphthenate, lead stearate, zinc naphthenate, zinc octolate, tin oleate, dibutyl tin maleate, manganese naphthenate, cobalt naphthenate, and acetyl aceton iron; inorganic metal salts, such as stannic chloride, zinc chloride and aluminum chloride; di-t-butyl diperphthalate; acid anhydrides, such as carboxylic acid anhydride, maleic anhydride, phthalic anhydride, lauric anhydride, pyromellitic anhydride, trimellitic anhydride, hexahydrophthalic anhydride; hexahydropyromellitic anhydride and hexahydrotrimellitic anhydride. Examples of suitable free radical curing agents include peroxides and azo compounds such as benzoyl peroxide, lauroyl peroxide, tertiary-butyl peroxide, octanoyl peroxide, acetyl peroxide, para-chlorobenzoyl peroxide, butyl peroctoates, dicumyl peroxide, azoisobutylonitrile, 2,2′-azobispropane, 2,2′-azobis(2-methyl-propanenitrile), 2,2′-azobis(2-methyl-butanenitrile), m,m′-azoxystyrene, and hydrozones.

The curing agent may also be a cure accelerator, such as those used for epoxy curing agents, and may be selected from the group consisting of triphenylphosphine, alkyl-substituted imidazoles, imidazolium salts, onium salts, quartenary phosphonium compounds, onium borates, metal chelates, and 1,8-diazacyclo[5.4.0]undex-7-ene.

Metal compounds also can be employed as curing agents, or accelerators, for cyanate ester resin systems and include, but are not limited to, metal napthenates, metal acetylacetonates (chelates), metal octoates, metal acetates, metal halides, metal imidazole complexes, and metal amine complexes.

Any suitable method for making a multilayer film may be employed. In one embodiment the top and bottom layers are formed individually and then laminated together to form a multilayer adhesive film. Suitable lamination temperatures vary according to the Tg of the specific film, and a typical range is 50 to 100° C. Lamination pressures are generally 5 to 60 psi.

The practitioner may also choose to include additional components in either the top or bottom layer of the multilayer adhesive film, for the purpose of tailoring the film properties to suit a particular semiconductor package or manufacturing process. Such components are of types and amounts known in the art, including but not limited to fillers, coupling agents, adhesion promoters, surfactants, wetting agents, flow control agents, air release agents, tackifying resins, and solvents.

One or more fillers may be included in the top and/or bottom layer of the multilayer adhesive film to adjust numerous properties including but not limited to rheology, stress, coefficient of thermal expansion, electrical and/or thermal conductivity, and modulus. The particular type of filler is not critical to the present invention and can be selected by one skilled in the art to suit the needs of the specific end use. Fillers may be conductive or nonconductive. Non-limiting examples of suitable conductive fillers include carbon black, graphite, gold, silver, copper, platinum, palladium, nickel, aluminum, silicon carbide, boron nitride, diamond, and alumina. Non-limiting examples of suitable nonconductive fillers include alumina, aluminum hydroxide, silica, vermiculite, mica, wollastonite, calcium carbonate, titania, sand, glass, barium sulfate, zirconium, carbon black, organic fillers, and halogenated ethylene polymers, such as, tetrafluoroethylene, trifluoroethylene, vinylidene fluoride, vinyl fluoride, vinylidene chloride, and vinyl chloride. The filler particles may be of any appropriate size ranging from nano size to several mils. The choice of such size for any particular package configuration is within the expertise of one skilled in the art. Filler may be present in an amount from 0 to 95 wt % of a film layer before B-staging, excluding solvent content.

In one embodiment, a coupling agent, or adhesion promoter, may be included in the top and/or bottom layer of the multilayer adhesive film. Adhesion promoter selection will depend on the application requirements and specific resin chemistry employed. Adhesion promoters, if used, will be used in an effective amount, typically up to 5 wt % of a film layer before B-staging, excluding solvent content. Examples of suitable adhesion promoters include: epoxy-type silane coupling agent, amine-type silane coupling agent, mercapto-type silane coupling agent; gamma-methacryloxypropyltrimethoxysilane; glycidoxypropyl trimethoxysilane; Z6040 epoxy silane, Z6030 methacryloxypropyltrimethoxysilane or Z6020 amine silane available from Dow Corning; A186 Silane, A187 Silane, A174 Silane, or A1289 available from OSI Silquest; Organosilane SI264 available from Degussa; Johoku Chemical CBT-1 Carbobenzotriazole available from Johoku Chemical; functional benzotriazoles; thiazoles; titanates; and zirconates.

In a further embodiment, a surfactant may be added to the top and/or bottom layer of the multilayer adhesive film. Suitable surfactants include silicones, polyethylene glycol, polyoxyethylene/polyoxypropylene block copolymers, ethylene diamine based polyoxyethylene/polyoxypropylene block copolymers, polyol-based polyoxyalkylenes, fatty alcohol-based polyoxyalkylenes, and fatty alcohol polyoxyalkylene alkyl ethers. Surfactants, if used, will be used in an effective amount: a typical effective amount is an amount up to 5 wt % of a film layer before B-staging, excluding solvent content.

In another embodiment a wetting agent may be included in the top and/or bottom layer of the multilayer adhesive film. Wetting agent selection will depend on the application requirements and the specific resin chemistry utilized. Wetting agents, if used, will be used in an effective amount: a typical effective amount is up to 5 wt % of a film layer before B-staging, excluding solvent content. Examples of suitable wetting agents include Fluorad FC-4430 Fluorosurfactant available from 3M, Clariant Fluowet OTN, BYK W-990, Surfynol 104 Surfactant, Crompton Silwet L-7280, Triton X100 available from Rhom and Haas, Propylene glycol with a preferable Mw greater than 240, Gama-Butyrolactone, castor oil, glycerin or other fatty acids, and silanes.

In a further embodiment, a flow control agent may be included in the top and/or bottom layer of the multilayer adhesive film. Flow control agent selection will depend on the application requirements and specific resin chemistry employed. Flow control agents, if used, will be present in an effective amount: an effective amount is an amount up to 20 wt % of a film layer before B-staging, excluding solvent content. Examples of suitable flow control agents include Cab-O-Sil TS720 available from Cabot, Aerosil R202 or R972 available from Degussa, fumed silicas, fumed aluminas, or fumed metal oxides.

In a further embodiment, an air release agent (defoamer) may be included in the top and/or bottom layer of the multilayer adhesive film. Air release agent selection will depend on the application requirements and specific resin chemistry employed. Air release agents, if used, will be used in an effective amount. A typical effective amount will be up to 5 wt % of a film layer before B-staging, excluding solvent content. Examples of suitable air release agents include Antifoam 1400 available from Dow Corning, DuPont Modoflow, and BYK A-510.

In some embodiments the top and/or bottom layer of the multilayer adhesive film are formulated with tackifying resins in order to improve adhesion and introduce tack; examples of tackifying resins include naturally-occurring resins and modified naturally-occurring resins; polyterpene resins; phenolic modified terpene resins; coumarons-indene resins; aliphatic and aromatic petroleum hydrocarbon resins; phthalate esters; hydrogenated hydrocarbons, hydrogenated rosins and hydrogenated rosin esters. Tackifying resins, if used, will be used in an effective amount. A typical effective amount will be up to 5 wt % of a film layer before B-staging, excluding solvent content.

In some embodiments other components may be included in the top and/or bottom layer of the multilayer adhesive film, for example, diluents such as liquid polybutene or polypropylene; petroleum waxes such as paraffin and microcrystalline waxes, polyethylene greases, hydrogenated animal, fish and vegetable fats, mineral oil and synthetic waxes, naphthenic or paraffinic mineral oils.

Other additives, such as stabilizers, antioxidants, impact modifiers, and colorants, in types and amounts known in the art, may also be added to the top and/or bottom layer of the multilayer adhesive film.

Common solvents with a proper boiling point ranging from 25° C. to 230° C. may be added to the top and/or bottom layer of the multilayer adhesive film. Examples of suitable solvents that may be utilized include ketones, esters, alcohols, ethers, and other common solvents that are stable and dissolve the curable resins in the composition. Suitable solvents include γ-butyrolactone, propylene glycol methyl ethyl acetate (PGMEA), methyl ethyl ketone (MEK), toluene, ethyl acetate, and 4-methyl-2-pentanone.

One or more void reduction compounds may also be added to the top and/or bottom layers of the multilayer adhesive film. Suitable void reduction compounds include but are not limited to those having at least two Si—O bonds contiguous with each other and at least one reactive functionality. Non-limiting examples of these types of void reduction compounds include:

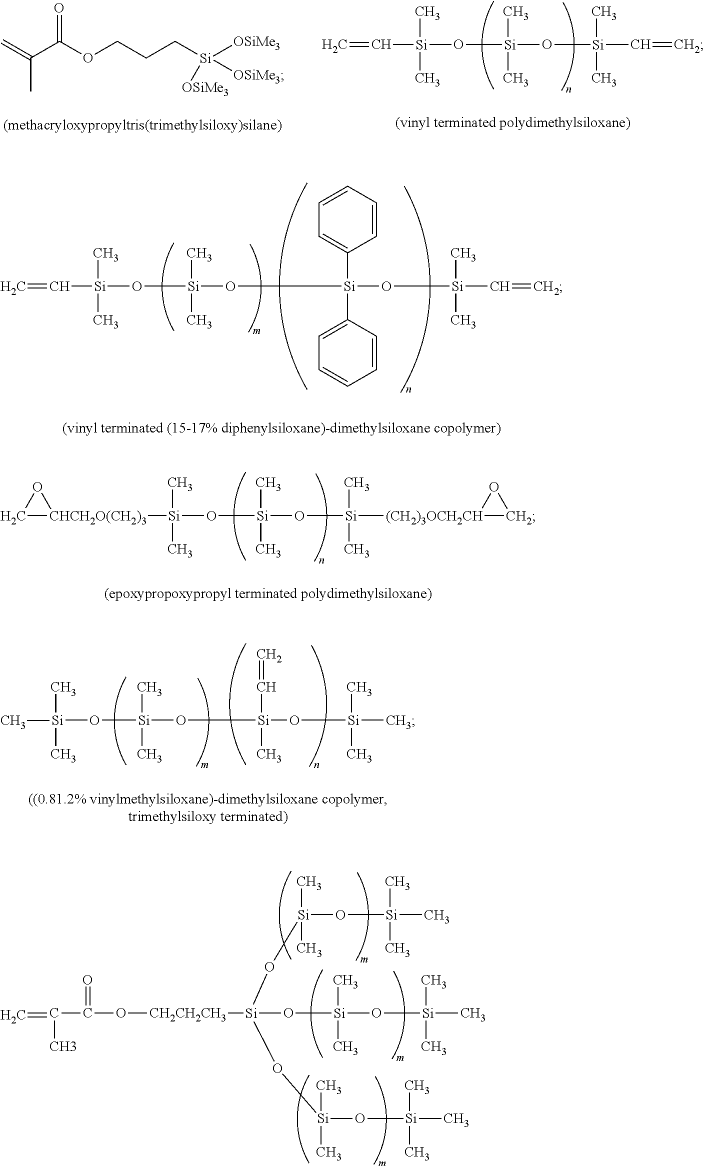

(methacryloxypropyl t-structure siloxane); and combinations of these.

Each of the layers of the multilayer adhesive film may be fabricated in any suitable manner known in the art. The individual layers may be fabricated in differing manners, or similar manners, as appropriate for the particular formulation and manufacturing environment employed. In one typical process, a film layer composition is coated onto a carrier, forming a thin, uniform layer. The composition is then B-staged to create a non-tacky, uniform layer of adhesive film. The hardening of the adhesive film layer may be accomplished in numerous ways, depending on the adhesive formulation employed.

In one embodiment the top and/or bottom layer composition comprises at least a liquid curable resin and a solvent. In this embodiment the adhesive is hardened to a non-tacky, or very low-flow, state by heating the composition sufficiently to evaporate the solvent and partially cure the curable resin or resins.

In another embodiment the top and/or bottom layer composition comprises a solid curable resin dissolved in a solvent. In this embodiment the adhesive is hardened to a non-tacky, or very low flow, state by heating the composition sufficiently to evaporate the solvent, leaving a non-tacky resin-based film. This method is particularly well-suited for the top layer of the multilayer adhesive film, as it does not require advancement of the resin to produce a non-tacky film layer, so a UV-curable resin system may be utilized.

In another embodiment the top and/or bottom layer composition comprises at least one liquid, thermally-curable resin. In this embodiment the composition is hardened to a non-tacky, or very low flow, state by heating the adhesive sufficiently to partially advance the curable resin to a non-tacky, or very low flow, state.

The carrier for the individual film layers and for the multilayer adhesive film may be anything to which the individual layer composition may be applied in a thin layer, and that will hold the composition during B-staging into a film. The carrier also may hold the film through application to an item to be bonded and/or additional processing steps, such as lamination to a wafer, another film layer, or to a dicing tape. One particularly suitable carrier is a release liner. Examples of suitable release liners include polyimide (PI) film, polyethylenenapthalate (PEN) film, and polyethyleneterephthalate (PET) film.

In one embodiment of the invention the multilayer adhesive film described above is attached to a dicing tape such that the bottom layer of the multilayer adhesive film is in direct contact with the dicing tape. The multilayer adhesive film is typically attached to the dicing tape via lamination. The dicing tape may be either a pressure sensitive adhesive (PSA) dicing tape or an ultraviolet (UV)-curable dicing tape. Typical tapes have an adhesive thickness of 3 to 30 μm on a polyolefin or poly vinyl chloride (PVC) carrier film that is 70 to 110 μm thick, however, one skilled in the art would appreciate that the tapes with different configurations may be selected to suit the particular industrial process to be utilized.

In another embodiment of the invention the BWBL film described above is attached to a semiconductor wafer such that the multilayer adhesive film is sandwiched between the semiconductor wafer and the dicing tape. In this construction the top layer of the multilayer adhesive film is in contact with the back, or inactive, side of the semiconductor wafer and the bottom layer of the multilayer adhesive film is in contact with the adhesive side of the dicing tape. The BWBL film is typically attached to the semiconductor wafer using a lamination process at a temperature of 40° to 100° C. and a pressure of 5 to 40 psi. In one embodiment the film is laminated to the semiconductor wafer at a temperature between 50° and 80° C., and a pressure between 15 and 30 psi.

Another embodiment of this invention is a process for attaching a semiconductor die to a substrate. First, a BWBL film is formed using the multilayer adhesive film and a dicing tape as described above. Next, the BWBL film is attached to a semiconductor wafer such that the top layer of the film is in direct contact with the back, or inactive, side of the semiconductor wafer, as described above. Then, the UV curable resin within the top layer is advanced, or substantially cured, through the application of ultraviolet radiation. The UV radiation is applied to the back side of the semiconductor wafer, such that it travels through the dicing tape and the bottom layer of the multilayer adhesive film to initiate curing of the UV-curable resin in the top layer of the multilayer adhesive film. The UV radiation may be supplied in any suitable manner and dosage for the particular manufacturing process employed. Typical UV radiation dosage ranges from 50 to 500 mJ/cm². In one embodiment the UV radiation is in the range of 100 to 300 mJ/cm². Next, the semiconductor wafer, along with the multilayer adhesive film attached thereto, is diced into a plurality of individual die structures. The dies may be any size and shape as suitable for the particular end use and the dicing may be achieved using any method known and practiced in the art. A chosen individual die structure is then picked up and placed on a substrate such that the adhesive film is disposed between the back side of the die and the substrate. This “pick and place” operation is typically accomplished using automated die attach equipment. Finally, the die is attached to the substrate by applying heat. Curing may be accomplished in a time ranging from a few seconds to two hours, and at temperatures ranging from 90 to 180° C. The cure may be accomplished in one step or in multiple steps.

It should be noted that in the process embodiment described above, the UV curing is key to preventing the top layer of the multilayer adhesive film from flowing at room temperature. This, in turn, prevents neighboring dies from sticking together after dicing when individual dies are removed from the dicing tape.

### EXAMPLES

Three exemplary multilayer adhesive films were prepared using the same bottom layer film formulation, while varying the top layer formulation. The layer compositions, excluding solvent, are specified in Table 1.

TABLE 1
Top and Botton Film Layer Compositions, wt %

| | | Top | Top | Top |
|---|---|---|---|---|
| Component | Bottom | Inv A | Inv B | Inv C |
| Rubber copolymer | 0 | 58.4 | 58.4 | 51.9 |
| Rubberized epoxy | 46.9 | 0 | 0 | 0 |
| Maleimide resin | 0 | 32.5 | 19.5 | 32.5 |
| Urethane acrylate resin | 0 | 0 | 13.0 | 0 |
| Multifunctional epoxy resin | 31.3 | 0 | 0 | 0 |
| Tert-butyl peroxide | 0 | 2.6 | 2.6 | 2.6 |
| thermal curing agent | | | | |
| Thermal catalyst | 0.6 | 0 | 0 | 0 |
| 4,4′-Diamino diphenyl | 7.8 | 0 | 0 | 0 |
| sulfone | | | | |
| thermal hardener | | | | |
| Silane coupling agent | 1.6 | 1.95 | 1.95 | 1.95 |
| Cyclohexylphenyl ketone | 0 | 2.6 | 2.6 | 2.6 |
| photoinitiator | | | | |
| Silica filler | 11.7 | 1.95 | 1.95 | 1.95 |

Each layer was prepared by mixing all the components using a high shear mixture at approximately 5000 rpm for 30 minutes until a homogeneous mixture was obtained. To the above compositions 50-80 wt % methyl ethyl ketone (MEK) solvent was added to dissolve all solid resins and to enable the mixture to be uniformly applied to a release liner. The mixtures were degassed in a vacuum chamber to allow air bubbles to be released. The mixtures were then coated onto silicone-coated release liner and dried in a convection oven at 100° C. for 3 minutes to form a film. The mixtures were applied in sufficient quantity such that after drying (B-staging) the top layer films were approximately 20 μm thick, and the bottom layer films were approximately 40 μm thick.

Samples of top layer films were tested with a rheometer to measure melt viscosity before UV irradiation. The samples of top layer films were then exposed to 500 mJ/cm² UV irradiation and tested again for melt viscosity. The results of this testing are shown in Table 2.

TABLE 2
Melt Viscosity of Top Layer Films Before and After UV
Irradiation, (poise)

| | Top layer Inv A | | Top layer Inv B | | Top layer Inv C | |
|---|---|---|---|---|---|---|
| | Before | After | Before | After | Before | After |
| Temp | UV | UV | UV | UV | UV | UV |
| 100° C. | 89750 | 122500 | 99250 | 137600 | 80700 | 106200 |
| 120° C. | 68450 | 108900 | 76310 | 192200 | 66610 | 119400 |
| 150° C. | 31190 | 92440 | 56130 | 260100 | 39040 | 135200 |
| 180° C. | 9600 | 61520 | 101000 | 382500 | 20430 | 148900 |
| 200° C. | 10240 | | | | 20010 | 165600 |

Samples of top layer films were laminated to bottom layer films using a roll laminator at 80° C. under 20 psi pressure, to form corresponding multilayer adhesive films. It should be noted that the top layer film samples had not yet been irradiated when they were laminated to the bottom layer films to form the multilayer adhesive film test specimens.

The multilayer adhesive films were tested for die shear strength, weight loss, peel strength, re-attach, and pickup performance. Specimen were prepared for die shear strength testing by laminating the selected multilayer adhesive film to a dicing tape at room temperature to form a BWBL, having the bottom layer of the multilayer adhesive film against the dicing tape and the top layer of the multilayer adhesive film exposed. The BWBL film was then laminated to a silicon wafer, with the top layer of the film in contact with the back, or inactive, side of the wafer, at 65° C. and 20 psi. The film on the back of the wafer was then exposed to UV radiation at 200 mJ/cm². The wafer was diced into individual die structures having the multilayer adhesive film attached. Individual die structures were picked up, placed on a larger silicon substrate, and thermally cured at 175° C. for one hour. Die shear strength was tested on a Dage die shear strength tester at room temperature and at 260° C. Five specimens were tested for each sample, and an arithmetic average value reported. In general, die shear strength of greater than 1.0 kg_{f}/die is required when testing 100×100 mil die at 260° C. It should be noted that for the purposes of these examples, 80×80 mil die were employed. Since a smaller die would typically be expected to give a lower die shear strength reading with equivalent adhesives, a reading of greater than 1.0 kg_{f}/die on the 80×80 mil die would be considered to exceed the typical requirement.

Weight loss at various temperatures was tested using a Perkin-Elmer thermogravimetric analyzer (TGA) at 10° C./minute ramp rate. Weight loss is typically tested in adhesive films to ensure they do not have excessive outgassing that could cause voids and other performance problems in the final assembly. Typically, less than 0.8% weight loss at 150° C. is required.

Peel strength was evaluated by laminating the multilayer adhesive film to a PSA dicing tape at room temperature such that the bottom layer of the film was in contact with the adhesive (PSA) side of the dicing tape, forming a BWL film. One inch wide specimens of BWL films were cut. The BWL film specimens were laminated to a silicon substrate using double-sided tape (between the bottom layer of the multilayer film and the substrate), such that the dicing tape was exposed opposite the substrate. The dicing tape was then peeled off the multilayer adhesive film at an angle of 180°. Peel strength is tested to ensure the adhesive film does not stick too strongly to the dicing tape. A very high peel strength could cause the adhesive film to delaminate from the semiconductor die, and remain on the dicing tape during die pickup. Typically, peel strength of less than 0.2 N/cm at room temperature is required.

Die reattach and pickup were evaluated by removing the release liner from the bottom layer of the multilayer adhesive film, and laminating it to a PSA dicing tape at room temperature, such that the bottom layer of the multilayer adhesive film was against the adhesive (PSA) side of the dicing tape, forming a BWBL film. The release liner was then removed from the top layer of the BWBL film (which was originally the top layer of the multilayer adhesive film), and the BWBL film was laminated to the back, or inactive, side of a 100 μm thick silicon wafer at 55° C. and 20 psi pressure with the top layer of the BWBL film against the back side of the wafer. The back side of the silicon wafer with the BWBL attached was then exposed to irradiation at 500 mJ/cm2 dosage to cure the UV-curable resin in the top layer of the multilayer adhesive film. The wafer, with BWBL attached, was then diced into individual die structures, having multilayer adhesive film attached to their backsides and being able to pull away from the dicing tape of the BWBL film. Immediately after dicing, several individual die structures were manually picked up from the diced wafer and it was noted whether or not any of the adjacent die structures stuck to the one being picked up. If any adjacent die structures stuck to the one being picked up, the sample was noted to have re-attach and pick-up was rated as “poor”. If, however, no adjacent die structures stuck to the one being picked up, the sample was noted to have “no” re-attach and pick-up was rated as “good”. The diced wafer was then allowed to sit at room temperature for 3 days and the pick-up testing procedure was repeated to determine whether the multilayer adhesive film had flowed sufficiently, in that time, to cause re-attach problems to emerge. The results of the testing of the multilayer adhesive film samples are presented in Table 3.

TABLE 3
Multilayer Adhesive Film Properties

| | | Inv A | Inv B | Inv C |
|---|---|---|---|---|
| Thickness, μm | Upper layer | 20 | 20 | 20 |
| | Bottom layer | 40 | 40 | 40 |
| Die shear strength | Room Temp | 15 | 22 | 14 |
| (kg_{f}/die) | 260° C. | 1.2 | 1.0 | 1.7 |
| Weight loss (wt %) | 150° C. | 0.62 | 0.41 | 0.66 |
| | 180° C. | 1.04 | 0.61 | 1.15 |
| | 200° C. | 1.37 | 0.76 | 1.65 |
| | 250° C. | 2.08 | 1.23 | 3.26 |
| | 300° C. | 2.69 | 2.67 | 4.55 |
| Peel strength, N/cm | | 0.15 | 0.14 | 0.15 |
| Re-attach, immediate | | No | No | No |
| Pick-up, immediate | | Good | Good | Good |
| Re-attach, 3 days | | No | No | No |
| Pick-up, 3 days | | Good | Good | Good |

Many modifications and variations of this invention can be made without departing from its spirit and scope, as will be apparent to those skilled in the art. The specific embodiments described herein are offered by way of example only, and the invention is to be limited only by the terms of the appended claims, along with the full scope of equivalents to which such claims are entitled.

What is claimed:

1. An adhesive film comprising (a) a top layer that is substantially UV curable and that has a glass transition temperature of 50° C. or less; and (b) a bottom layer that is substantially not UV-curable.

2. The adhesive film of claim 1 wherein the top layer comprises a UV curable resin selected from the group consisting of an acrylate and a bismaleimide.

3. The adhesive film of claim 1 wherein the bottom layer comprises an epoxy resin.

4. The adhesive film of claim 1 wherein the top layer has a glass transition temperature between 0 and 20° C.

5. An adhesive film laminated on a support tape wherein the adhesive film comprises (a) a top layer that is substantially UV curable and that has a glass transition temperature of 50° C. or less; and (b) a bottom layer that is substantially not UV-curable.

6. The adhesive film of claim 5 wherein the top layer comprises a UV curable resin selected from the group consisting of an acrylate and a bismaleimide.

7. The adhesive film of claim 5 wherein the bottom layer comprises an epoxy resin.

8. The adhesive film of claim 5 wherein the support tape is a dicing tape selected from the group consisting of a PSA dicing tape and a UV-curable dicing tape.

9. A semiconductor wafer attached to an adhesive film, in which the adhesive film comprises (a) a top layer that is adhered to the semiconductor wafer, is substantially UV curable, and has a glass transition temperature of 50° C. or less; and (b) a bottom layer that is substantially not UV-curable.

10. The semiconductor wafer of claim 9 wherein the top layer comprises a UV curable resin selected from the group consisting of an acrylate and a bismaleimide.

11. The semiconductor wafer of claim 9 wherein the bottom layer comprises an epoxy resin.

12. A process for attaching a semiconductor die to a substrate comprising the steps of:
a. providing an adhesive film comprising (a) a top layer that is substantially UV curable and has a glass transition temperature of 50° C. or less; and (b) a bottom layer that is substantially not UV-curable;
b. providing a support tape having a backing side and an adhesive side;
c. attaching the adhesive film to the support tape by contacting the bottom layer of the adhesive film with the adhesive side of the support tape, thereby exposing the top layer of the adhesive film, and thereby forming a bundled wafer backside lamination film;
d. providing a semiconductor wafer having an active side and an inactive side;
e. attaching the bundled wafer backside lamination film to the semiconductor wafer by contacting the top layer of the adhesive film contact with the inactive side of the semiconductor wafer;
f. advancing the top layer;
g. dicing the semiconductor wafer and attached multilayer adhesive film into a plurality of individual die structures;
h. picking up a chosen individual die structure;
i. providing a substrate;
j. placing the chosen individual die structure on the substrate such that the adhesive film is disposed between the back side of the die and the substrate; and
k. attaching the individual die structure to the substrate using heat.

13. The process of claim 12 wherein the top layer comprises a UV curable resin selected from the group consisting of an acrylate and a bismaleimide.

14. The process of claim 12 wherein the bottom layer comprises an epoxy resin.

15. The process of claim 12 wherein the top layer has a glass transition temperature between 0 and 20° C.

16. The process of claim 12 wherein the support tape is a dicing tape selected from the group consisting of a PSA dicing tape and a UV-curable dicing tape.

17. A method of preventing individually diced dies from sticking to one another comprising the steps of:
a) providing an adhesive film comprising (a) a top layer that is substantially
UV curable and has a glass transition temperature of 50° C. or less; and (b) a bottom layer that is substantially not UV-curable;
b) providing a support tape having a backing side and an adhesive side;
c) attaching the adhesive film to the support tape by contacting the bottom layer of the adhesive film with the adhesive side of the support tape, thereby exposing top layer of the adhesive film, and thereby forming a bundled wafer backside lamination film;
d) providing a semiconductor wafer having an active side and an inactive side;
e) attaching the bundled wafer backside lamination film to the semiconductor wafer by contacting the top layer of the adhesive film with the inactive side of the semiconductor wafer;
f) advancing the top layer;
g) dicing the semiconductor wafer and attached multilayer adhesive film into a plurality of individual die structures; and
h) picking up a chosen individual die structure.

18. The method of claim 17 wherein the top layer comprises a UV curable resin selected from the group consisting of an acrylate and a bismaleimide.

19. The method of claim 17 wherein the bottom layer comprises an epoxy resin.

20. The method of claim 17 wherein the support tape is a dicing tape selected from the group consisting of a pressure sensitive adhesive (PSA) dicing tape and a UV-curable dicing tape.
